(19) United States
(12) Patent Application Publication
(10) Pub. No.: US 2025/0105142 A1
(43) Pub. Date: Mar. 27, 2025

(54) RADIO FREQUENCY INDUCTOR

(71) Applicant: Taiwan Semiconductor Manufacturing Company LTD, Hsinchu (TW)

(72) Inventors: Bo-Yu Chiu, Taoyuan (TW); Ming-Da Cheng, Taoyuan (TW); Chang-Jung Hsueh, Taipei (TW); You Ru Lee, Kaohsiung (TW); Chung-Long Chang, Hsinchu (TW)

(21) Appl. No.: 18/371,577

(22) Filed: Sep. 22, 2023

(51) Int. Cl. H01L 23/522; H01L 23/532

(52) U.S. Cl. CPC H01L 23/5227; H10D 1/20; H01L 23/53228; H01L 23/53295

(57) ABSTRACT

An interconnect structure is formed, including a plurality of patterned metallization layers spaced apart by dielectric material on the semiconductor wafer. A radio frequency (RF) inductor device is formed on the interconnect structure. To this end, a copper inductor coil is formed on the interconnect structure by plating. The plated copper inductor coil is textured copper having at least 90% (111) orientation. The plated copper inductor coil is electrically connected with at least one patterned metallization layer of the interconnect structure. Upper domes may be formed on turns of the plated copper inductor coil.

### BACKGROUND

The following relates to the semiconductor device and manufacturing arts, back end-of-line (BEOL) processing arts, radio frequency (RF) inductor arts, BEOL inductor arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a top view of a radio frequency (RF) inductor coil.

FIG. 2 diagrammatically illustrates a sectional view of a portion of a RF inductor device taken along a Section S-S indicated in FIG. 1.

FIG. 3 diagrammatically illustrates an RF inductor such as that illustrated in FIGS. 1 and 2 in a nonlimiting illustrative back end-of-line (BEOL) context.

FIGS. 4 and 5 diagrammatically illustrate top views of additional RF inductor layouts that may be suitably used for RF inductors as disclosed herein.

FIG. 6 illustrates by way of a flowchart a nonlimiting illustrative example of a manufacturing process for manufacturing an RF inductor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Radio frequency (RF) inductors are incorporated into the back end-of-line (BEOL) processing of integrated circuit (IC) chips for various purposes, such as obtaining improved quality factor (Q-factor) for RF signals. Placement of the RF inductor in the BEOL processing has some advantages over forming it on the semiconductor wafer during front end-of-line (FEOL) processing. An RF inductor is a relatively large-area device, and hence placing it on the semiconductor wafer can occupy valuable wafer area. A BEOL RF inductor can also be positioned closer to RF signal input/output (I/O) to/from the IC chip.

Various factors affect inductor performance, including proximity effect, skin effect, and others. The skin effect refers to the lack of RF penetration into the material, such that electric fields at RF frequencies are confined to the surface of an electrically conductive material. The skin depth δ of an RF signal in a conductive material is given by:

$$δ = \sqrt{\frac{ρ}{π μ f}} \qquad ( 1 )$$

where f is the RF frequency, ρ is the electrical resistivity of the conductor, μ is the magnetic permeability of the conductor, and π denotes the mathematical “pi” constant. Reduced skin depth δ means that a smaller portion of the inductor (specifically, a thin surface portion of the turns of the inductor) carries the entire RF load. This can reduce RF coupling efficiency since most of the inductor material is shielded from RF coupling by the skin effect, and can potentially damage the inductor itself due to excessive Joule heating concentrated at the surface of the conductors of the inductor. One way to counter this is to employ a physically larger inductor so as to increase the total surface area of the inductor, but this makes IC chip miniaturization more difficult.

From Equation (1), it is seen that the skin depth δ decreases (and hence the detrimental skin effect increases) with increasing RF frequency f, and decreases with reduced electrical resistivity ρ. The RF frequency f is typically fixed for a given IC chip design, and so it is desirable to reduce the resistivity ρ, as lower electrical resistance of the inductor material results in reduced skin effect.

Embodiments disclosed herein advantageously provide inductors for BEOL processing that are made of low resistance copper. However, making a BEOL inductor from copper has its own disadvantages. Notably, due to the skin effect the RF currents are flowing on the outer skin of the copper inductor. This concentrates Joule heating on the surface, which can result in elevated operating temperatures that approach the melting point of copper (about 1084° C. for pure copper), leading to thermal instability.

To overcome these difficulties, some embodiments of the copper inductor disclosed herein employ textured copper having at least 90% (111) orientation, and in some embodiments at least 97% (111) orientation. In such high texture (111) copper material, the grains are predominantly oriented in the (111) orientation. This has several benefits. It results in predominantly low-angle grain boundaries since most grains have close to (111) orientations. The low-angle grain boundaries reduce the contribution of the grain boundaries to the electrical resistance of the high texture (111) copper material, thus resulting in the high texture (111) copper material having lower electrical resistivity p compared with other types of copper. High texture (111) copper material also exhibits improved hardness and electromigration and oxidation resistance compared with high texture copper material of other orientations (e.g., high texture (101) copper).

In some embodiments, the copper inductor coil is advantageously formed on an insulator layer by plating, which can produce high texture (111) copper material having at least 90% (111) orientation, and in some embodiments at least 97% (111) orientation. Characterization techniques such as X-ray diffraction (XRD), electron backscatter diffraction (EBSD), and cross-sectional scanning electron microscopy (SEM) can be used to quantitatively measure the percentage of the copper having the desired (111) orientation, thus enabling empirical determination of the percentage (111) orientation of the high texture (111) copper material. Plating parameters such as pulse current magnitude and frequency, and the plating temperature, can be empirically optimized using test runs characterized by XRD and/or EBSD to optimize the plating to obtain high texture (111) copper material having the desired at least 90% (111) orientation, or the desired least 97% (111) orientation. In some embodiments, the plating may employ both forward and reverse pulses during the plating process. The choice of seed layer can also impact the texture and can be similarly empirically optimized.

In some embodiments, the copper inductor coil is advantageously modified to include an upper dome on turns of the copper inductor coil. The upper dome increases the total surface area of the turns of the copper inductor coil, thus providing improved RF coupling by way of increased total surface area without a concomitant increase in the layout area occupied by the RF inductor.

In some embodiments, both of these features are combined: the copper inductor coil comprises textured copper having at least 90% (111) orientation, and in some embodiments at least 97% (111) orientation; and also includes an upper dome on the turns of the copper inductor coil. The resulting inductor advantageously has improved electrical performance (e.g., lower resistance and higher Q-factor) and improved hardness and thermal stability.

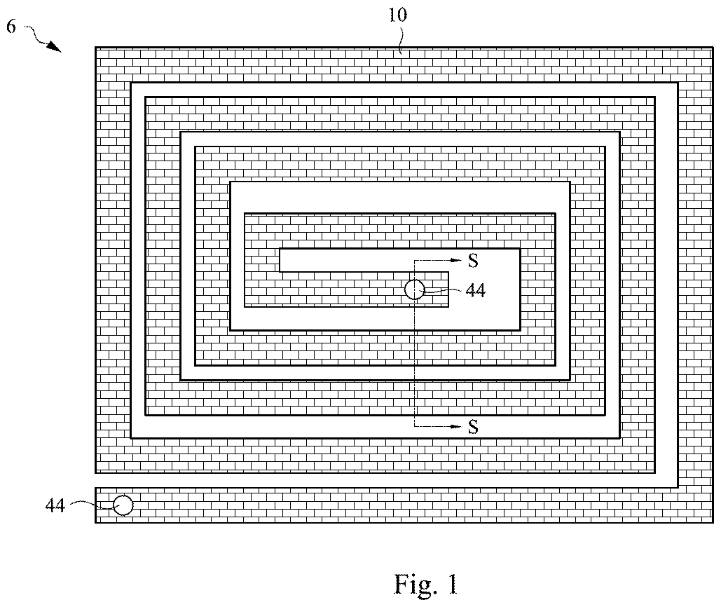

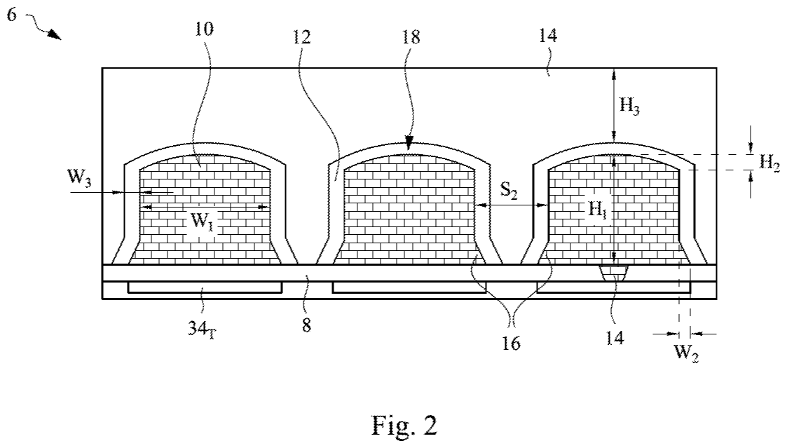

With reference now to FIGS. 1 and 2, a radio frequency (RF) inductor device 6 is shown by a top view (FIG. 1) and a sectional view shown in FIG. 2 taken along Section S-S line indicated in FIG. 1. The RF inductor device 6 includes an insulator layer 8 and a copper inductor coil 10 (i.e., inductor 10) disposed on the insulator layer 8. The copper inductor coil 10 has a plurality of turns (illustrative four turns), but the number of turns can be one, two, three, illustrative four, five, six, or more turns. Typically, the inductance increases with an increasing number of turns (ideally, the inductance increases with the square of the number of turns, although this assumes perfect coupling between the turns which is usually not the case). It can be preferable in some IC chip designs to limit the number of turns, since increasing the number of turns increases the layout area of the inductor 12, which can be undesirable if it is desired to miniaturize the IC chip. While FIG. 1 shows a top view of the RF inductor device 6 including the copper inductor coil 10, FIG. 2 shows Section S-S including additional components that may be included, such as the aforementioned insulator layer 8 and one or more dielectric overlayers such as an insulating coating 12 disposed over the copper inductor coil 10 (and optionally over portions of the insulator layer 8 not covered by the copper inductor coil 10), and a polyimide 14 encapsulating the copper inductor coil 10 (and its insulating coating 12).

The copper inductor coil 10 is made of textured copper having at least 90% (111) orientation, and more preferably at least 97% (111) orientation. As already discussed, this high texture (111) copper has benefits over other forms of copper, as high texture (111) copper provides benefits such as reduced electrical resistance (for a given inductor coil layout/number of turns), and improved hardness and electromigration and oxidation resistance compared with other a coil of another type of copper. The use of high texture (111) copper can provide improvements in the RF performance and reliability of the inductor 10, including improved electrical performance (e.g., lower resistance and higher Q-factor) and improved hardness and thermal stability. Typically, these benefits increase with increasing percentage having the (111) orientation. In some embodiments, at least 97% (111) orientation is preferred to obtain desired low electrical resistance and high thermal stability of the high texture (111) copper inductor coil 10.

Without loss of generality, FIG. 2 illustrates dimensions of the high texture (111) copper inductor coil 10 including a height H₁ in a height direction that is transverse to the insulator layer 8, a width W₁ of the turns of the high texture (111) copper inductor coil 10, and a spacing S₁ between neighboring turns of the copper inductor coil 10. As seen in FIG. 2, the spacing S₁ is measured from one edge of one turn to the closest edge of the next turn. The dimensions H₁, W₁, and S₁ are selected for ease of processing/fabrication of the copper inductor coil 10 and for reliability of the copper inductor coil 10. Based on these considerations, in some nonlimiting illustrative embodiments the coil height H₁ is in a range of one micron to 7 microns (that is, 1 μm≤H₁≤7 μm), the turn width W₂ is in a range of one micron to 50 microns (that is, 1 μm≤W₁≤50 μm), and the spacing S₁ is in a range of one micron to 50 microns (that is, 1 μm≤S₁≤50 μm).

In the illustrative embodiment, the turns of the inductor 10 include footings 16 disposed on the insulator layer 8 and extending away a distance W₂ (indicated in FIG. 2) from the opposite sides of each turn. In some nonlimiting illustrative embodiments, the distance W₂ is between 0.1 micron and one micron (that is, 0.1 μm≤W₂≤1 μm). The footings 16 are optional (or, put another way, W₂=0 is contemplated). The insulating coating 12 has a thickness W₃ indicated in FIG. 2. In some nonlimiting illustrative embodiments, the thickness W₃ is in a range of 0.5 micron to two microns (that is, 0.5 μm≤W₃≤2 μm). Again, these ranges for W₂ and W₃ are selected for ease of processing/fabrication of the copper inductor coil 10 and for reliability of the copper inductor coil 10, and should be considered to be nonlimiting illustrative examples.

As seen in FIG. 2, the turns of the copper inductor coil 10 have an upper dome 18 on turns of the copper inductor coil. The upper dome 18 of each turn is distal from the insulator layer 8. As previously discussed, the upper dome 18 increases to the total surface area of the inductor 10 compared with the turns having planar top surfaces, thus advantageously increasing the total surface area for RF coupling so as to improve overall RF coupling of the inductor 10. In some nonlimiting illustrative examples, the upper dome 18 may have a height H₂ in a range of between 0.2 microns and one micron (that is, 0.2 μm≤H₂≤1 μm). The height H₂ is measured along the same height direction transverse to the insulator layer 8 along which the overall height H₁ of the coil 10 is measured, and as seen in FIG. 2 the overall height H₁ of the coil 10 includes the height H₂ of the dome 18. As further seen in FIG. 2, the polyimide 14 encapsulating the inductor 10 extends a height H₃ (again in the height direction) above the top of the domes 18. In some nonlimiting illustrative embodiments, the height H₃ is in a range of one micron to seven microns (that is, 1 μm≤H₃≤7 μm). Again, these ranges for H₂ and H₃ are selected for ease of processing/fabrication of the copper inductor coil 10 and for reliability of the copper inductor coil 10, and should be considered to be nonlimiting illustrative examples.

The insulator layer 8 and the optional insulating coating 12 can comprise any suitable electrically insulating material, such as (by way of nonlimiting illustrative example) an oxide (e.g., stoichiometric SiO₂ or a nonstoichiometric SiₓO_{y} where 0<(x,y)<1), a nitride (e.g., stoichiometric Si₃N₄ or nonstoichiometric SiₓN_{y} where 0<(x,y)<1), a silicon oxynitride, a multilayer of two or more insulator materials, or so forth.

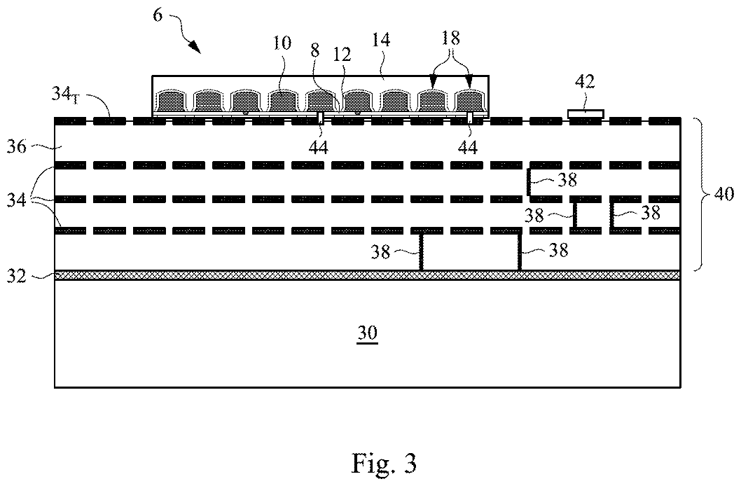

With reference to FIG. 3, the RF inductor device 6 of FIGS. 1 and 2 is shown in sectional view in the context of BEOL processing. A typical manufacturing workflow for fabricating an integrated circuit (IC) includes front end-of-line (FEOL) processing and back end-of-line (BEOL) processing stages. During the FEOL processing, various electronic, optoelectronic, photonic, or other devices such as transistors, photodetectors, and/or so forth are fabricated on and/or in a semiconductor wafer 30 such as a silicon, silicon-on-insulator (SOI), germanium, gallium arsenide (GaAs), or other semiconductor wafer. This produces a layer or region of semiconductor devices 32 on a surface of the semiconductor wafer 30. These devices may, for example, be RF signal processing devices, as a nonlimiting illustrative example.

The BEOL processing follows the FEOL processing, and includes forming a stack of patterned metallization layers 34 spaced apart by dielectric material 36, sometimes referred to as intermetal dielectric (IMD) material 36. The patterned metallization layers 34 may, by way of nonlimiting illustrative example, comprise an electrically conductive material such as copper, aluminum, a copper alloy, or an aluminum alloy. The patterned metallization layers 34 are typically not high texture (111) copper, although it is contemplated from the patterned metallization layers 34 to be high texture (111) copper. The IMD material 36 is typically an oxide, such as silicon dioxide (SiO₂) formed by plasma-enhanced atomic layer deposition (PEALD), chemical vapor deposition (CVD), or another deposition technique. Electrically conductive vias 38 pass through the IMD material 36 to interconnect the patterned metallization layers 34. The vias 38 may, for example, comprise tungsten, copper, or another electrically conductive material. A typical BEOL processing sequence entails successive iterations to build up the stack of patterned metallization layers 34. Each iteration may, for example, include: depositing IMD material on the last patterned metallization layer (or, on the layer or region of semiconductor devices 32 in the case of the initial M0 metallization layer); photolithographic processing of the IMD material to form via openings passing through the IMD material to access the last patterned metallization layer (or the layer or region of semiconductor devices 32 in the case of the initial M0 metallization layer); followed by metal deposition to fill the via openings to form vias 38; and deposition and photolithographic patterning of the next metallization layer. This process can be iteratively repeated to build up the stack of patterned metallization layers 34. The stack of patterned metallization layers 34 and interconnecting vias 38 formed during BEOL processing provide electrically conductive circuitry for interconnecting transistors, photodetectors, and/or other devices of the layer or region of semiconductor devices 32 formed on a surface of the semiconductor wafer 10 during the FEOL processing.

The structure comprising the stack of patterned metallization layers 34 and the IMD material 36 may, for example, constitute an interconnect structure 40. In some embodiments, a topmost patterned metallization layer 34r serves as the contact surface for bonding the overall device (e.g., the device layer 32 and the interconnect structure 40) to a printed circuit board, another IC chip, or the like (not shown). Bonding pads 42 (only one representative example of which is shown in FIG. 3) may be formed on the top surface of the interconnect structure 40 (e.g., on the topmost patterned metallization layer 34T) to serve as under-bump metallization (UBM) for bonding bumps (not shown) used to bond the IC chip to the printed circuit board, other IC chip, or the like. The bonding bumps may be solder bumps, copper balls, solder-coated copper balls, or the like.

Typically, the bonding bumps 42 are made of copper or a copper alloy. However, in some embodiments it is contemplated that the bonding pads 42 may also be made of high texture (111) copper, and in such embodiments the formation of the high texture (111) copper bonding bumps 42 may be performed at the same time as the formation of the high texture (111) copper inductor coil 10, for example in a single plating process that forms both the high texture (111) copper bonding bumps 42 and the high texture (111) copper inductor coil 10.

With continuing reference to FIG. 3 and with further reference back to FIGS. 1 and 2, the high texture (111) copper inductor coil 10 is electrically connected with the interconnect structure 40, e.g., with the topmost patterned metallization layer 34T, by electrical vias 44 passing through the insulator layer 8 to contact the topmost patterned metallization layer 34T. The vias 44 may be formed of the same high texture (111) copper material that formed the high texture (111) copper inductor coil 10, and may, for example, be formed by the same process (e.g., plating) used to form the copper inductor coil 10. That is, the plating process may operate to fill via openings photolithographically formed in the insulator layer 8 with high texture (111) copper to form the vias 44 and the plating process continues to form the high texture (111) copper inductor coil 10. It is noted that the patterned metallization layer 34T with which the high texture (111) copper inductor coil 10 is electrically connected by the vias 44 is typically not made of high texture (111) copper (that is, the connected metallization layer 34T is typically not made of high texture (111) copper). However, it is alternatively contemplated for the connected metallization layer 34 to also be made of high texture (111) copper.

FIG. 1 illustrates possible locations for the vias 44 at opposite ends of the spiral coil 10. (It is noted that the vias 44 are underneath the high texture (111) copper inductor coil 10, and so they would not typically be visible in the top view of FIG. 1, hence the indicated locations of the vias 44 in FIG. 1 should be considered diagrammatic representations). However, it should be noted that the locations of the vias 44 shown in FIG. 1 is merely a nonlimiting illustrative example.

The RF inductor device 6, and more particularly the high texture (111) copper inductor coil 10, can serve various functions in the IC chip. For example, the high texture (111) copper inductor coil 10 can serve as the inductor in an LC (inductor-capacitor), RL (resistor-inductor), or RLC (resistor-inductor-capacitor) sub-circuit of RF circuitry of the IC chip. For example, an LC or RLC circuit can form a resonant circuit that can perform RF frequency filtering, improve the Q-factor of RF signal processing, or so forth. These are merely some nonlimiting illustrative examples.

In the example of FIG. 3, the RF inductor device 6 including the high texture (111) copper inductor coil 10 is formed on (and hence disposed at) a top surface of the interconnect structure 40; that is, formed on/disposed at the surface of the interconnect structure 40 opposite from the layer or region of semiconductor devices 32. However, it is contemplated to instead have the RF inductor device 6 embedded within the interconnect structure. For example, if the interconnect structure includes 10 patterned metallization layers 34 (enumerated, without loss of generality, as layers M0-M9), then as a nonlimiting example the first 5 patterned metallization layers 34 (i.e., layers M0-M4) could be formed, after which the RF inductor device 6 is formed and contacts the M4 patterned metallization layer by the vias 44, followed by formation of the latter 5 patterned metallization layers (i.e., layers M5-M9).

With reference back to FIG. 1, the illustrative high texture (111) copper inductor coil 10 is rectangular, and includes four turns. However, this is merely one nonlimiting illustrative example. Both number of turns and the geometrical shape of the turns can be chosen based on various factors such as the desired inductance, the acceptable layout area occupied by the high texture (111) copper inductor coil, and so forth. Typically, the inductance increases with the number of turns, e.g., ideally inductance increases with the square of the number of turns. On the other hand, more turns can increase the layout area for the inductor, which may be undesirable if IC chip miniaturization is a goal.

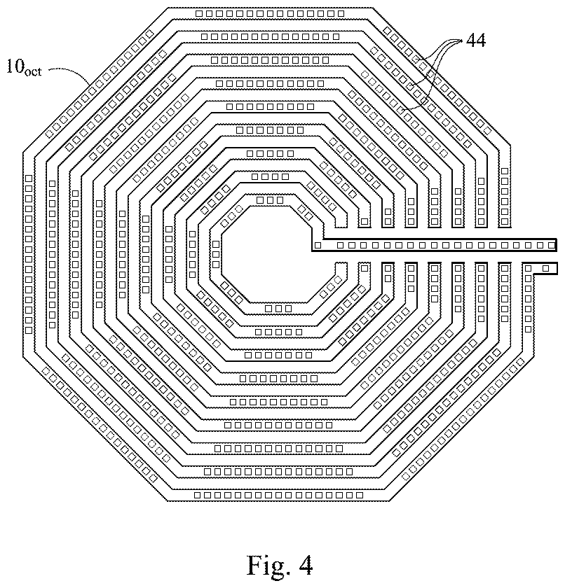

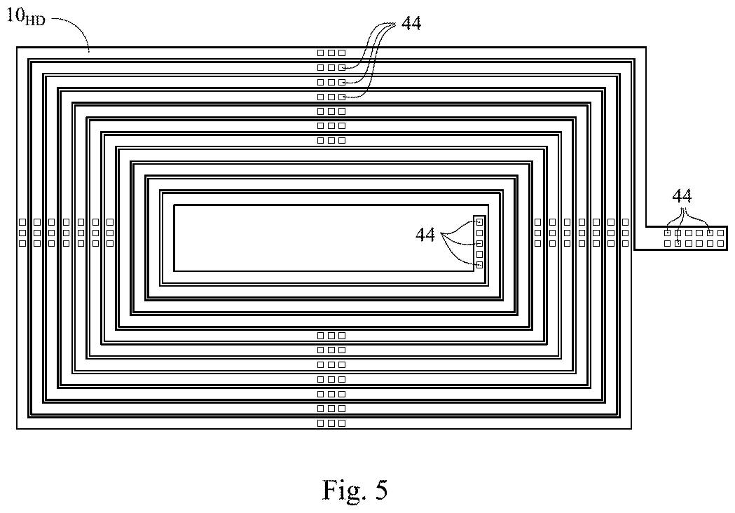

With reference to FIGS. 4 and 5, two additional nonlimiting illustrative examples of suitable layouts for the high texture (111) copper inductor coil are shown. In the example of FIG. 4, a high texture (111) copper inductor coil 10_{oct} is octagonal, that is, eight-sided. Put another way, the turns of the high texture (111) copper inductor coil 10_{oct} of FIG. 4 are octagonal in shape. The illustrative high texture (111) copper inductor coil 10_{oct} of FIG. 4 has nine (9) octagonal turns; however, the number of turns can be chosen for the desired application (e.g., the desired inductance and layout area).

In the example of FIG. 5, a high texture (111) copper inductor coil 10_{HD} is rectangular, that is, has rectangular turns, as in the embodiment of FIG. 1. However, the high texture (111) copper inductor coil 10_{HD} is has more turns than the high texture (111) copper inductor coil 10 of FIG. 1. The illustrative high texture (111) copper inductor coil 10_{HD} of FIG. 5 has eleven (11) rectangular turns. Moreover, the high texture (111) copper inductor coil 10_{HD} of FIG. 5 has these 11 turns packed with a higher density, by reducing the spacing S₁ between adjacent turns (where S₁ was defined previously with reference to FIG. 2). There can be tradeoffs in such designs—for example, reducing the spacing S₁ can provide a more compact inductor, but if the inductor operates at high voltage then a small spacing S₁ can increase the possibility of a voltage arc across neighboring turns.

FIGS. 4 and 5 also illustrate different options for the locations of the vias 44 connecting the inductor with the underlying patterned metallization layer 34T. In the embodiment of FIG. 4, the high texture (111) copper inductor coil 10_{oct} has connecting vias 44 distributed over the length of the octagonal coil. In the example of FIG. 5, the connecting vias 44 are grouped into four groups contacting the outermost fourth through tenth turns, along with five vias 44 contacting the end of the innermost turn and ten vias 44 contacting the end of the outermost turn. Again, it is to be understood that the locations of the vias 44 are diagrammatically indicated in FIGS. 4 and 5—in practice, they are located underneath the respective high texture (111) copper inductor coils 10_{oct} and 10_{HD} and hence are occluded from view in the top views of FIGS. 4 and 5.

Although not visible in the top views of FIGS. 4 and 5, it will be appreciated that these embodiments may optionally include the upper dome 18 on the turns of the respective high texture (111) copper inductor coils 10_{oct} and 10_{HD}. In some embodiments, the high texture (111) copper material of the respective high texture (111) copper inductor coils 10_{oct} and 10_{HD} has at least 90% (111) orientation, and in some embodiments at least 97% (111) orientation.

Again, it is to be understood that the coil layout embodiments of FIGS. 1, 4, and 5 are merely nonlimiting illustrative examples. More generally, the high texture (111) copper inductor coil can have turns of various geometries (e.g., rectangular, hexagonal, octagonal, or so forth) and can in general have any number of turns (e.g., one turn, two turns, three turns, five turns, ten turns, fifteen turns, et cetera).

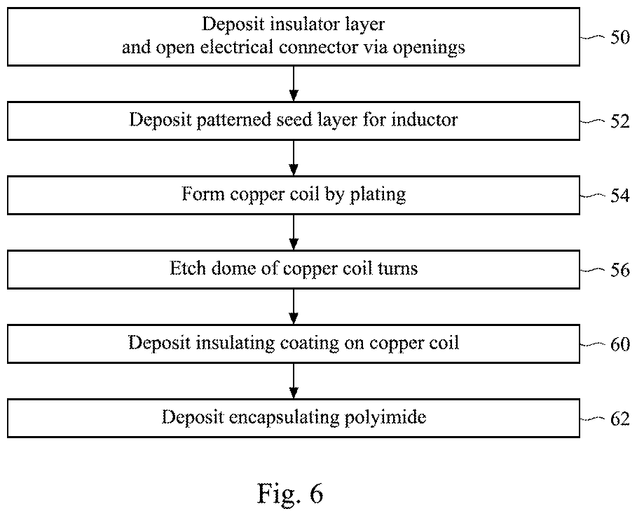

With reference now to FIG. 6, a suitable method for fabricating the RF inductor device 6 including the high texture (111) copper inductor coil 10 is described. The method of FIG. 6 assumes the interconnect structure 40 of FIG. 3 has been formed. That is, the method of FIG. 6 starts after formation of the interconnect structure 40. (However, if the RF inductor device 6 is to be embedded in the interconnect structure 40 then the method of FIG. 6 could be performed after some, but not all, patterned metallization layers 34 are formed, after which the method of FIG. 6 would be performed, followed by formation of the remaining patterned metallization layers 34 of the interconnect structure).

The method of FIG. 6 starts with an operation 50 in which the insulator layer 8 is deposited on the interconnect structure 40, and openings destined to be filled to form the vias 44 are opened in the insulator layer 8 by photolithographic processing. The operation 50 can entail forming the insulator layer 8 of a suitable electrically insulating material such as an oxide, a nitride, a silicon oxide, silicon nitride, or silicon oxynitride, a multilayer of two or more insulator materials, or so forth. The insulator layer 8 may be formed by any suitable deposition technique for depositing the insulating material, such as physical vapor deposition (PVD), chemical vapor deposition (CVD), or so forth. The openings for the vias 44 are suitably formed by photolithographic processing, i.e., a photoresist layer (not shown) is disposed on the blanket insulator layer 8 and exposed via a photomask and the exposed photoresist developed to form openings in the photoresist aligned with the openings to be formed in the insulator layer 8, followed by suitable chemical etching that etches the openings in the insulator layer 8 through the openings in the photoresist, followed by photoresist stripping.

In an operation 52, a patterned seed layer for subsequent plating of the high texture (111) copper inductor coil 10 is deposited by PVD, CVD, or another suitable technique. The seed layer may be copper, but could be another electrically conductive material that is suitable for seeding electroplating of high texture (111) copper. The patterned seed layer is typically thin, e.g. substantially thinner than the height H₁ of the plated high texture (111) copper inductor coil 10 (see definition of H₁ in FIG. 2). The operation 52 may, for example, include depositing a blanket layer of the seed material and then photolithographically patterning the blanket layer to form the patterned seed layer of copper or another suitable plating seed material.

In an operation 54, the high texture (111) copper inductor coil 10 is formed by plating. Parameters of the electroplating (also known in the art as electrochemical deposition, or electrodeposition) are chosen to form the high texture (111) copper material with the desired high texture (e.g., at least 90% (111) orientation, and in some embodiments at least 97% (111) orientation). As previously mentioned, the electroplating parameters, such as pulse current magnitude and frequency and the plating temperature, are suitably empirically optimized using test runs in which high texture (111) copper layers of the desired thickness (e.g., corresponding to the desired coil height H₁ as indicated in FIG. 2) are formed with different electroplating parameters; and the textures of the respective test high texture (111) copper layers are characterized by XRD, EBSD, and/or SEM to determine the percentage (111) orientation in each test layer. The choice of patterned seed layer formed in the operation 52 can be similarly (co-) optimized. In some embodiments, the plating performed in the operation 54 may employ both forward and reverse pulses during the plating process, which can increase the (111) texture.

Notably, the area extent of the plating is limited to the patterned seed layer formed in the previous operation 52. This is because the electrically insulating layer 8 is not a suitable conductor for the plating process. Hence, the layout of the high texture (111) copper inductor coil 10 (or, alternatively, of the high texture (111) copper inductor coil 10_{oct} of the embodiment of FIG. 4 or the high texture (111) copper inductor coil 10_{HD} of the embodiment of FIG. 5) is determined by the photolithographic patterning of the seed layer.

The bonding pads 42 may be made of a material such as aluminium or an aluminum alloy. In some contemplated embodiments, however, some or all of the bonding pads 42 (see FIG. 3 and related discussion) may be formed of high texture (111) copper in the operations 52 and 54. To do so, the patterning of the seed layer in the operation 52 includes forming seed layer portions corresponding to both the high texture (111) copper inductor coil 10 and the bonding pads 42. In this way, the subsequent plating operation 54 plates the high texture (111) copper material both on the portion of the patterned seed layer corresponding to the coil thus forming the high texture (111) copper inductor coil 10, and also on the portions of the patterned seed layer corresponding to the bonding pads 42 (thus forming the bonding pads 42 of the same plated high texture (111) copper material as forms the coil 10). It will be appreciated that the bonding pads 42 can similarly benefit from being made of the high texture (111) copper material, thus conferring benefits for the bonding pads 42 such as reduced electrical resistance of the bonding pads 42 and improved thermal stability for the bonding pads 42.

In embodiments in which the turns of the high texture (111) copper inductor coil 10 are to include the upper dome 18, this can subsequently be formed in an operation 56 by a suitable etching process. In one nonlimiting illustrative approach, an isotropic etch can be applied which will preferentially etch the upper corner of the turn due to there being two exposed surfaces at the corner (namely the top surface and the side surface). This preferential etching of the corners forms the upper surfaces of the turns into the desired shape of the upper dome 18. Again, empirical optimization can be performed, for example using cross-sectional SEM to directly image the shape of the domes 18 achieved for different etching parameters. It will be appreciated that the etching may also contribute to forming the optional footings 16 of the turns of the high texture (111) copper inductor coil 10.

In an operation 60, the optional insulating coating 12 is disposed on the high texture (111) copper inductor coil 10 (and optionally on portions of the surface of the insulator layer 8 between the turns of the copper inductor coil 10). The insulating coating 12 can be formed by any suitable deposition technique (e.g., PVD, CVD, et cetera) and can comprise any suitable electrically insulating material, such as an oxide, a nitride, a silicon oxide, silicon nitride, or silicon oxynitride, a multilayer of two or more insulator materials, or so forth.

In an operation 62, the optional encapsulating polyimide 14 is formed. In one approach, polyimide material is deposited up to a thickness of at least H₁+H₃ (where H₁ and H₃ are defined as shown in FIG. 2), followed by chemical-mechanical polishing to planarize the upper surface of the polyimide with the final thickness as shown in FIG. 2 (e.g., the thickness H₃ above the top of the upper domes 18 of the coil 10).

In the illustrative method of FIG. 6, the high texture (111) copper inductor coil 10 is formed by plating in the operation 54, with the high texture (111) copper being plated onto the patterned seed layer formed in the operation 52. However, other methods for forming the high texture (111) copper inductor coil 10 are contemplated, such as sputtering as another nonlimiting illustrative example. In this illustrative alternative embodiment (not shown), the operations 52 and 54 would be replaced by a sputtering operation to form a blanket layer of high texture (111) copper, followed by suitable photolithographic patterning of the blanket high texture (111) copper to form the high texture (111) copper inductor coil 10.

In the following, some further embodiments are described.

In a nonlimiting illustrative embodiment, a method of forming a radio frequency (RF) inductor device is disclosed. The method includes forming an insulator layer, and forming a copper inductor coil on the insulator layer by plating. The copper inductor coil comprises textured copper having at least 90% (111) orientation.

In a nonlimiting illustrative embodiment, a method of forming an RF inductor device is disclosed. The method comprises: forming semiconductor devices on a semiconductor wafer; after forming the semiconductor devices, forming an interconnect structure comprising a plurality of patterned metallization layers spaced apart by dielectric material on the semiconductor wafer; and forming a copper inductor coil on the interconnect structure by plating. The copper inductor coil comprises textured copper having at least 90% (111) orientation. The plated copper inductor coil is electrically connected with at least one patterned metallization layer of the interconnect structure.

In a nonlimiting illustrative embodiment, an RF inductor device includes an insulator layer, and a copper inductor coil having a plurality of turns disposed on the insulator layer. The copper inductor coil comprises textured copper having at least 90% (111) orientation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a radio frequency (RF) inductor device, the method comprising:
forming an insulator layer; and
forming a copper inductor coil on the insulator layer by plating, wherein the copper inductor coil comprises textured copper having at least 90% (111) orientation.

2. The method of claim 1, wherein the copper inductor coil comprises textured copper having at least 97% (111) orientation.

3. The method of claim 1, further comprising:
depositing an insulating coating over the copper inductor coil.

4. The method of claim 3, further comprising:
after depositing the insulating coating, encapsulating the copper inductor coil in polyimide.

5. The method of claim 1, wherein the forming of the copper inductor coil includes forming an upper dome on turns of the copper inductor coil.

6. The method of claim 1, wherein the turns of the copper inductor coil are rectangular or octagonal.

7. The method of claim 1, further comprising;
performing back end-of-line (BEOL) processing to form a plurality of patterned metallization layers spaced apart by a dielectric material and electrically interconnected by conductive vias passing through the dielectric material;
wherein the copper inductor coil is formed as part of the BEOL processing and is electrically connected with at least one patterned metallization layer of the plurality of patterned metallization layers.

8. A method of forming a radio frequency (RF) inductor device, the method comprising:
forming semiconductor devices on a semiconductor wafer;
after forming the semiconductor devices, forming an interconnect structure comprising a plurality of patterned metallization layers spaced apart by dielectric material on the semiconductor wafer; and
forming a copper inductor coil on the interconnect structure by plating, wherein the copper inductor coil comprises textured copper having at least 90% (111) orientation and wherein the copper inductor coil is electrically connected with at least one patterned metallization layer of the interconnect structure.

9. The method of claim 8, wherein the copper inductor coil comprises textured copper having at least 97% (111) orientation.

10. The method of claim 8, wherein the forming of the copper inductor coil includes forming an upper dome on turns of the copper inductor coil.

11. A radio frequency (RF) inductor device comprising:
an insulator layer; and
a copper inductor coil having a plurality of turns disposed on the insulator layer, wherein the copper inductor coil comprises textured copper having at least 90% (111) orientation.

12. The RF inductor device of claim 11, wherein the copper inductor coil comprises the textured copper having at least 97% (111) orientation.

13. The RF inductor device of claim 12, wherein:
the copper inductor coil has a height in a height direction that is transverse to the insulator layer of between one micron and seven microns; and
the turns of the copper inductor coil have a width of between one micron and 50 microns.

14. The RF inductor device of claim 13, wherein the turns of the copper inductor coil are spaced apart by a distance of between one micron and 50 microns.

15. The RF inductor device of claim 13, wherein the turns of the copper inductor coil further include footings disposed on the insulator layer and extending between 0.1 micron and one micron away from opposite sides of the turn.

16. The RF inductor device of claim 13, further comprising;
an insulating coating disposed over the copper inductor coil, the insulating coating having a thickness of between 0.5 micron and two microns.

17. The RF inductor device of claim 12, wherein the turns of the copper inductor coil have an upper dome distal from the insulator layer.

18. The RF inductor device of claim 17, wherein:
the copper inductor coil including the upper dome has a height in a height direction that is transverse to the insulator layer of between one micron and seven microns; and
the dome has a height in the height direction of between 0.2 microns and one micron.

19. The RF inductor device of claim 11, wherein the turns of the copper inductor coil have an upper dome distal from the insulator layer.

20. The RF inductor device of claim 11, further comprising;
an interconnect structure comprising a plurality of patterned metallization layers spaced apart by a dielectric material and electrically interconnected by conductive vias passing through the dielectric material, wherein the copper inductor coil is disposed in or on the interconnect structure; and
at least two electrical conductors passing through the insulating layer and connecting the copper inductor coil with at least one patterned metallization layer of the interconnect structure.
